(19) United States
(12) Patent Application Publication
(10) Pub. No.: US 2014/0335342 A1
(43) Pub. Date: Nov. 13, 2014

(54) MOBILE PHONE COVER FABRIC HAVING ELECTROMAGNETIC SHIELDING FUNCTION AND METHOD OF MANUFACTURING THE SAME

(71) Applicants: Seong-keun Lee, Busan (KR); KYUNG-EUN TEXTILE INDUSTRIAL CO., LTD., Busan (KR)

(72) Inventor: Seong-keun Lee, Busan (KR)

(73) Assignees: KYUNG-EUN TEXTILE INDUSTRIAL CO., LTD., Busan (KR); Seong-keun Lee, Busan (KR)

(21) Appl. No.: 14/283,606

(22) Filed: May 21, 2014

Related U.S. Application Data
(63) Continuation of application No. PCT/KR2013/007177, filed on Aug. 8, 2013.

(30) Foreign Application Priority Data
May 10, 2013 (KR) 10-2013-0053187

(51) Int. Cl. H05K 9/00; B32B 37/14

(52) U.S. Cl. CPC H05K 9/0081; B32B 37/14; H05K 9/0088; H05K 9/0084
USPC 428/221; 156/60

(57) ABSTRACT

This invention relates to a mobile phone cover fabric having an electromagnetic shielding function and a method of manufacturing the same, and, more particularly, to a mobile phone cover fabric having an electromagnetic shielding function and a method of manufacturing the same, the method including applying a first polycarbonate resin composition on a release paper and drying it; applying a second polycarbonate resin composition on the first polycarbonate resin composition and drying it; applying a binder on the second polycarbonate resin composition and bonding-laminating an electromagnetic shielding fabric on the binder; drying the bonding-laminated electromagnetic shielding fabric and rolling it on a winder; and aging the rolled electromagnetic shielding fabric at 60˜80° C. in an aging room.

### REFERENCE TO RELATED APPLICATIONS

This is a continuation of pending International Patent Application PCT/KR2013/007177 filed on Aug. 8, 2013, which designates the United States and claims priority of Korean Patent Application No. 10-2013-0053187 filed on May 10, 2013, the entire contents of which are incorporated herein by reference.

### FIELD OF THE INVENTION

The present invention relates to a mobile phone cover fabric having an electromagnetic shielding function and a method of manufacturing the same, and, more particularly, to a mobile phone cover fabric having an electromagnetic shielding function and a method of manufacturing the same, wherein the electromagnetic shielding capability of a mobile phone can be improved using a composition comprising a polycarbonate resin and carbon nanotubes.

### BACKGROUND OF THE INVENTION

Generally, electromagnetic waves are a type of energy arising due to the use of electric power and are composite waves of electric and magnetic fields. Such electromagnetic waves, in order of increasing frequency, are classified into gamma rays, X-rays, UV light, visible light, IR rays, radio waves (ultrahigh frequency, high frequency, low frequency, ultralow frequency waves), micro waves, etc. Briefly, radio waves are a kind of electromagnetic wave having a frequency of at most 3000 GHz (3 trillion vibrations per second) and are indispensable in daily life.

Especially, mobile appliances such as mobile phones emit large amounts of electromagnetic waves in the form of radio waves to communicate with a base station through an antenna and a main body of the appliance. Furthermore, although there is still controversy about the hazards of electromagnetic waves generated by mobile phones, it is generally accepted that they are harmful to human bodies.

Also, the International Agency for Research on Cancer (IARC) under the World Health Organization (WHO) has classified electromagnetic waves generated by wireless communication appliances such as mobile phones, etc. into carcinogenic substances (2B grade), and has reported that the generation potential of brain tumors and acoustic neuroma of persons who used mobile phones every 30 min for 10 years or longer is increased by 40%.

Thereby, mobile phones in Korea follow the highly stringent electromagnetic wave emission standards of the United States, and are currently regulated to a SAR (Specific Absorption Rate) of 1.6 W/Kg or less.

To shield the electromagnetic waves generated by mobile phones, a conventional film is known, which is configured to include a heat dissipation tape layer attached to the back surface of a mobile phone, a copper foil film layer or a graphene layer formed on the back surface of the heat dissipation tape layer so as to shield electromagnetic waves and dissipate heat, a base layer formed on the back surface of the copper foil film layer or the graphene layer, and a hard coating layer formed on the lower surface of the base layer.

This film provides electromagnetic shielding and heat dissipation functions to a certain degree but suffers from being incapable of providing the high-level electromagnetic shielding function over time.

### SUMMARY OF THE INVENTION

Accordingly, the present invention has been made keeping in mind the above problems occurring in the related art, and the present invention is intended to provide a mobile phone cover fabric having an electromagnetic shielding function and a method of manufacturing the same, wherein electromagnetic waves generated by mobile phones may be completely shielded and heat dissipation performance may be improved.

The present invention provides a method of manufacturing a mobile phone cover fabric having an electromagnetic shielding function, comprising:

applying a first polycarbonate resin composition on a release paper and drying the first polycarbonate resin composition;

applying a second polycarbonate resin composition on the first polycarbonate resin composition and drying the second polycarbonate resin composition;

applying a binder on the second polycarbonate resin composition, and bonding-laminating an electromagnetic shielding fabric on the binder;

drying the bonding-laminated electromagnetic shielding fabric and rolling the dried electromagnetic shielding fabric on a winder; and

aging the rolled electromagnetic shielding fabric at 60-80° C. in an aging room.

As such, the first polycarbonate resin composition or the second polycarbonate resin composition may comprise 100 parts by weight of a polycarbonate resin, 10˜25 parts by weight of dimethylformamide (DMF), 30 50 parts by weight of methyl ethyl ketone (MEK), 25˜40 parts by weight of a toner and 2˜7 parts by weight of an antimicrobial agent.

The second polycarbonate resin composition may comprise 100 parts by weight of a polycarbonate resin, 10˜25 parts by weight of dimethylformamide (DMF), 30˜50 parts by weight of methyl ethyl ketone (MEK), and 10˜20 parts by weight of carbon nanotubes.

Furthermore, an antifouling agent may be applied on the surface of the first polycarbonate resin composition from which the release paper has been removed.

The electromagnetic shielding fabric may be formed by plating a fabric with a mixture of aluminum and nickel.

In addition, the present invention provides a mobile phone cover fabric having an electromagnetic shielding function, comprising:

a first polycarbonate resin composition;

a second polycarbonate resin composition applied on the first polycarbonate resin composition;

a binder applied on the second polycarbonate resin composition; and

an electromagnetic shielding fabric bonding-laminated on the binder.

As such, the first polycarbonate resin composition or the second polycarbonate resin composition may comprise 100 parts by weight of a polycarbonate resin, 10˜25 parts by weight of dimethylformamide (DMF), 30 50 parts by weight of methyl ethyl ketone (MEK), 25˜40 parts by weight of a toner and 2˜7 parts by weight of an antimicrobial agent.

The second polycarbonate resin composition may comprise 100 parts by weight of a polycarbonate resin, 10˜25 parts by weight of dimethylformamide (DMF), 30˜50 parts by weight of methyl ethyl ketone (MEK), and 10˜20 parts by weight of carbon nanotubes.

The electromagnetic shielding fabric may be formed by plating a fabric with a mixture of aluminum and nickel.

According to the present invention, the following effects can be expected.

Specifically, the electromagnetic shielding function can be primarily exhibited by virtue of an electromagnetic shielding fabric, and can be further improved thanks to the use of a composition including carbon nanotubes.

Also, heat dissipation performance can be enhanced using carbon nanotubes.

Also, the composition includes a polycarbonate resin, thereby improving the properties so as to suppress hydrolysis and yellowing.

### BRIEF DESCRIPTION OF THE DRAWINGS

FIG. 1 is a flowchart illustrating a process of manufacturing a mobile phone cover fabric having an electromagnetic shielding function according to a preferred embodiment of the present invention;

FIG. 2 is a cross-sectional view illustrating a mobile phone cover fabric manufactured according to a preferred embodiment of the present invention;

FIG. 3 is a test certificate illustrating results of measurement of antimicrobial activity of the mobile phone cover fabric manufactured according to a preferred embodiment of the present invention; and

FIGS. 4a to 4c show a test certificate illustrating results of measurement of electromagnetic shielding effectiveness of the mobile phone cover fabric manufactured according to a preferred embodiment of the present invention.

### DETAILED DESCRIPTION OF THE INVENTION

Hereinafter, a detailed description will be given of a mobile phone cover fabric having an electromagnetic shielding function and a method of manufacturing the same according to the present invention, with reference to the appended drawings and the embodiments.

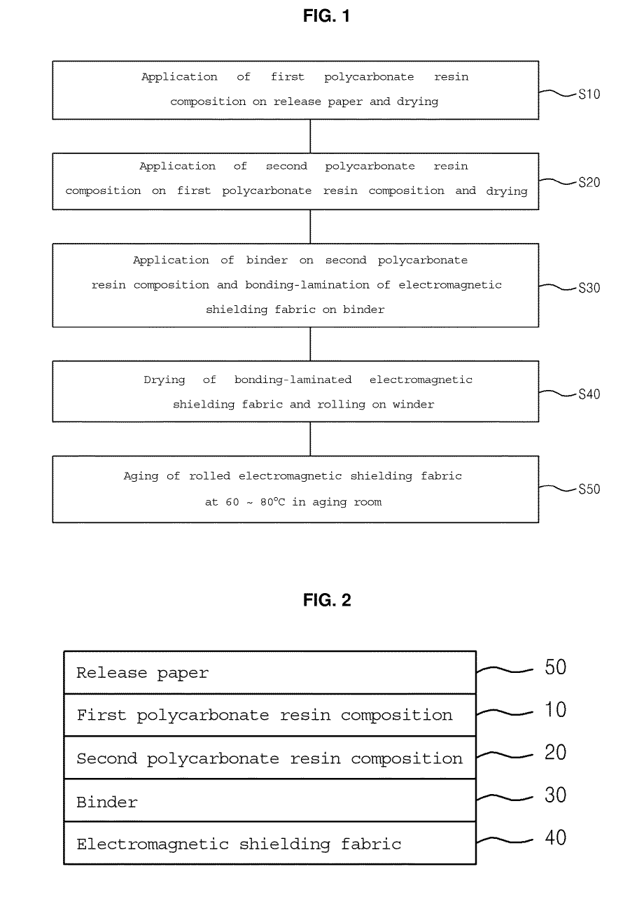

FIG. 1 is a flowchart illustrating a process of manufacturing a mobile phone cover fabric having an electromagnetic shielding function according to a preferred embodiment of the present invention, and FIG. 2 is a cross-sectional view illustrating a mobile phone cover fabric manufactured according to a preferred embodiment of the present invention.

With reference to FIGS. 1 and 2, the method of manufacturing the mobile phone cover fabric having an electromagnetic shielding function according to the present invention includes applying a first polycarbonate resin composition 10 on a release paper 50 and drying it (S10). Specifically, the first polycarbonate resin composition, which is prepared by adding a polycarbonate resin having high electromagnetic shielding efficiency with a toner so as to be toned and with an antimicrobial agent, is applied on the release paper and then dried.

As such, the first polycarbonate resin composition 10 comprises 100 parts by weight of a polycarbonate resin, 10˜25 parts by weight of dimethylformamide (DMF), 30˜50 parts by weight of methyl ethyl ketone (MEK), 25˜40 parts by weight of a toner, and 2˜7 parts by weight of an antimicrobial agent. Herein, dimethylformamide (DMF) is added in an amount of 10˜25 parts by weight, and preferably in an amount of about 20 parts by weight, based on 100 parts by weight of the polycarbonate resin. Also, methyl ethyl ketone (MEK) is used in an amount of 30˜50 parts by weight, and preferably in an amount of 40 parts by weight. The toner is provided in the form of a liquid including an additive such as a pigment, a dispersant, an anti-flooding agent, an anti-settling agent, etc. The toner is added in the form of a liquid so as for toning. The toner is used in an amount of 25˜40 parts by weight, and preferably in an amount of about 30 parts by weight, based on 100 parts by weight of the polycarbonate resin.

In order to improve antimicrobial activity of the fabric, the polycarbonate resin is added with an antimicrobial agent. The antimicrobial agent is used in an amount of 2˜7 parts by weight, and preferably in an amount of about 5 parts by weight, based on 100 parts by weight of the polycarbonate resin.

Subsequently, a second polycarbonate resin composition 20 is applied on the first polycarbonate resin composition 10 and dried (S20).

The second polycarbonate resin composition 20 is applied on the first polycarbonate resin composition 10, thus improving properties such as wear resistance, adhesion, etc.

The second polycarbonate resin composition 10 may be provided to be the same as the first polycarbonate resin composition. Alternatively, carbon nanotubes for improving heat dissipation performance and further increasing electromagnetic shielding effectiveness may be added, instead of the toner of the first polycarbonate resin composition 10. Specifically, the second polycarbonate resin composition 20 comprises 100 parts by weight of a polycarbonate resin, 10˜25 parts by weight of dimethylformamide (DMF), 30˜50 parts by weight of methyl ethyl ketone (MEK) and 10˜20 parts by weight of carbon nanotubes.

As such, dimethylformamide (DMF) is added in an amount of 10˜25 parts by weight, and preferably in an amount of about 20 parts by weight, based on 100 parts by weight of the polycarbonate resin. Also, methyl ethyl ketone (MEK) is used in an amount of 30˜50 parts by weight, and preferably in an amount of 40 parts by weight. The carbon nanotubes are used in an amount of 10˜20 parts by weight, and preferably in an amount of about 15 parts by weight.

Meanwhile, applying the first and the second polycarbonate resin composition 10, 20 may be carried out using a comma coater. Specifically, roll presses are spaced apart from each other by a thickness of the first and the second polycarbonate resin to be applied, after which the first and the second polycarbonate resin composition 10, 20 are poured and passed through the roll presses, so that the first and the second polycarbonate resin composition 10, 20 may be uniformly distributed and applied at a predetermined thickness corresponding to a distance between the roll presses which are apart from each other. As such, the first and the second polycarbonate resin composition 10, 20 are preferably applied to a thickness of 0.1˜0.15 mm. Furthermore, the rate passing through the roll presses is preferably set to 18 m/min. The drying temperature of the first and the second polycarbonate resin composition is preferably set to 110˜140° C.

Subsequently, a binder 30 is applied on the second polycarbonate resin composition 20, and an electromagnetic shielding fabric 40 is bonding-laminated on the binder 30 (S30). As such, the binder 30 is composed by adding 100 parts by weight of a polycarbonate resin with 10˜20 parts by weight of dimethylformamide (DMF), 30˜50 parts by weight of methyl ethyl ketone (MEK), 5˜10 parts by weight of a curing accelerator and 7˜15 parts by weight of a curing agent.

Dimethylformamide (DMF) is added in an amount of 10˜25 parts by weight, and preferably in an amount of about 15 parts by weight, based on 100 parts by weight of the polycarbonate resin. Also, methyl ethyl ketone (MEK) is used in an amount of 30˜50 parts by weight, and preferably in an amount of about 40 parts by weight. The curing accelerator is used in an amount of 5˜10 parts by weight, and preferably in an amount of about 8 parts by weight. The curing agent is used in an amount of 7˜15 parts by weight, and preferably in an amount of about 10 parts by weight. The binder is preferably applied to a thickness of 0.1˜0.2 mm, and then dried so as to be semi-dried at 80˜120° C., thus improving the sense of touch.

The electromagnetic shielding fabric 40 is imparted with an electromagnetic shielding function by plating a fabric with a mixture of aluminum and nickel.

Subsequently, the bonding-laminated electromagnetic shielding fabric 40 is dried and rolled on a winder (S40), and the rolled electromagnetic shielding fabric 40 is then aged at 60˜80° C. for about 24 hours in an aging room.

After aging, the release paper 50 is removed from the upper surface of the first polycarbonate resin composition 10, and then an antifouling agent (not shown) is further applied to prevent surface pollution.

In accordance with S10˜S50 (FIG. 1) of the method of manufacturing the electromagnetic shielding fabric as above, the first polycarbonate resin layer 10, the second polycarbonate resin layer 20, the binder 30 and the electromagnetic shielding fabric 40 are sequentially stacked on the release paper 50 (FIG. 2).

A mobile phone cover fabric may be more rapidly hydrolyzed due to the oil of human hands, undesirably causing surface breaking and cracking.

According to the present invention, however, the first and the second polycarbonate resin layer 10, 20 include polycarbonate, so that the properties thereof can be enhanced so as to suppress hydrolysis and yellowing.

### EXAMPLE

A first polycarbonate resin composition 10 was prepared by adding 100 parts by weight of a polycarbonate resin with 20 parts by weight of dimethylformamide (DMF), 40 parts by weight of methyl ethyl ketone (MEK), 30 parts by weight of a toner, and 5 parts by weight of an antimicrobial agent. This composition was applied on a release paper 50 and dried at 110˜140° C.

A second polycarbonate 20 which is the same as the first polycarbonate resin composition 10 was applied on the first polycarbonate resin composition 10, and then dried at 110˜140° C. which is the same as above.

Subsequently, a binder 30 was applied on the second polycarbonate resin composition 20, and an electromagnetic shielding fabric 40 formed by plating a fabric with a mixture of aluminum and nickel was bonding-laminated on the binder 30.

The binder 30 was composed by adding 100 parts by weight of a polycarbonate resin with 15 parts by weight of dimethylformamide (DMF), 40 parts by weight of methyl ethyl ketone (MEK), 8 parts by weight of a curing accelerator and 10 parts by weight of a curing agent.

The bonding-laminated electromagnetic shielding fabric 40 was dried and rolled on a winder, and then aged at 60˜80° C. in an aging room.

After aging, the release paper 50 was stripped from the first polycarbonate resin composition 10, and then an antifouling agent (not shown) was applied on the first polycarbonate resin composition 10 and dried at 130˜170° C.

The mobile phone cover fabric having an electromagnetic shielding function, as manufactured in the above example, was tested for antimicrobial activity by FITI Testing & Research Institute, Korea, and also for electromagnetic shielding effectiveness by Gumi Electronics & Information Technology Research Institute, Korea.

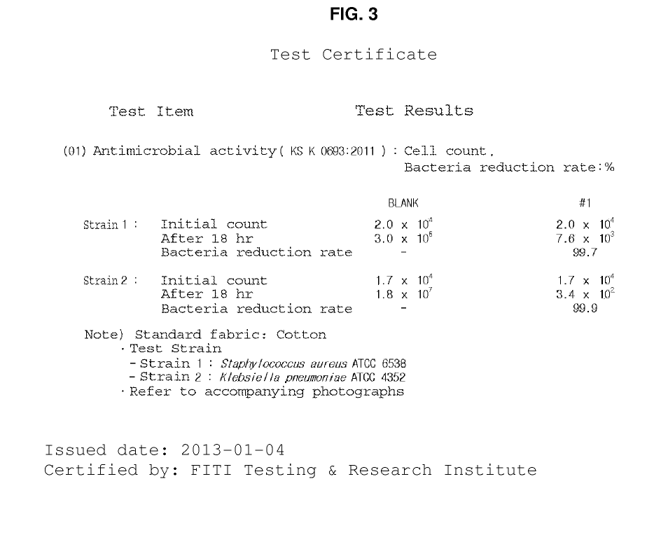

FIG. 3 illustrates the test certificate for antimicrobial activity of the mobile phone cover fabric manufactured according to a preferred embodiment of the present invention.

With reference to FIG. 3, bacteria reduction rates for Strain 1 (Staphy lococcus aureus ATCC 6538) and Strain 2 (Klebsiella pneumoniae ATCC 4352) were 99.7% and 99.9%, respectively, after 18 hours, thus achieving very high antimicrobial activity.

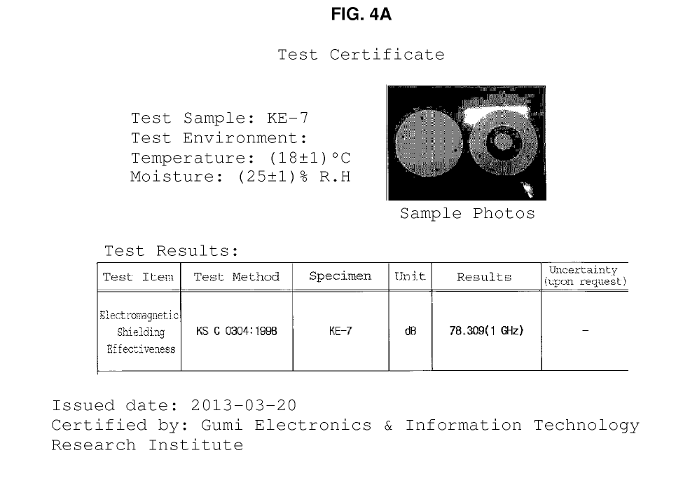

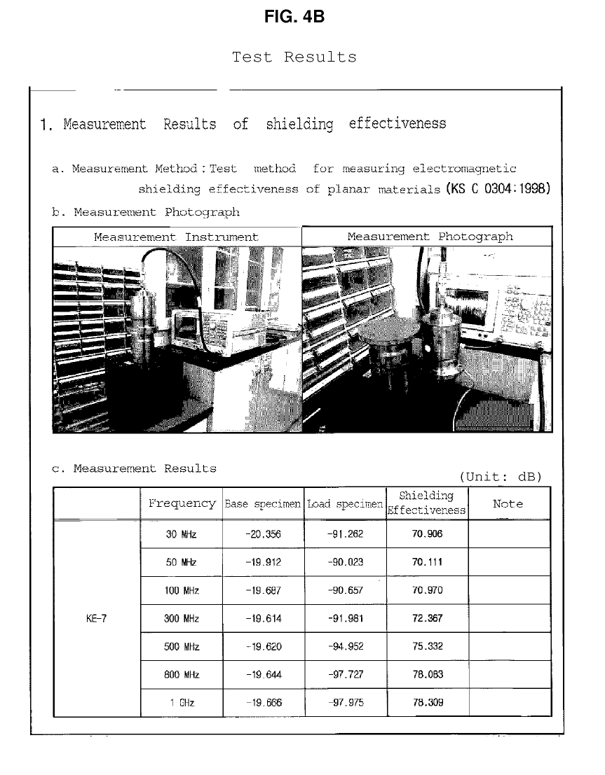

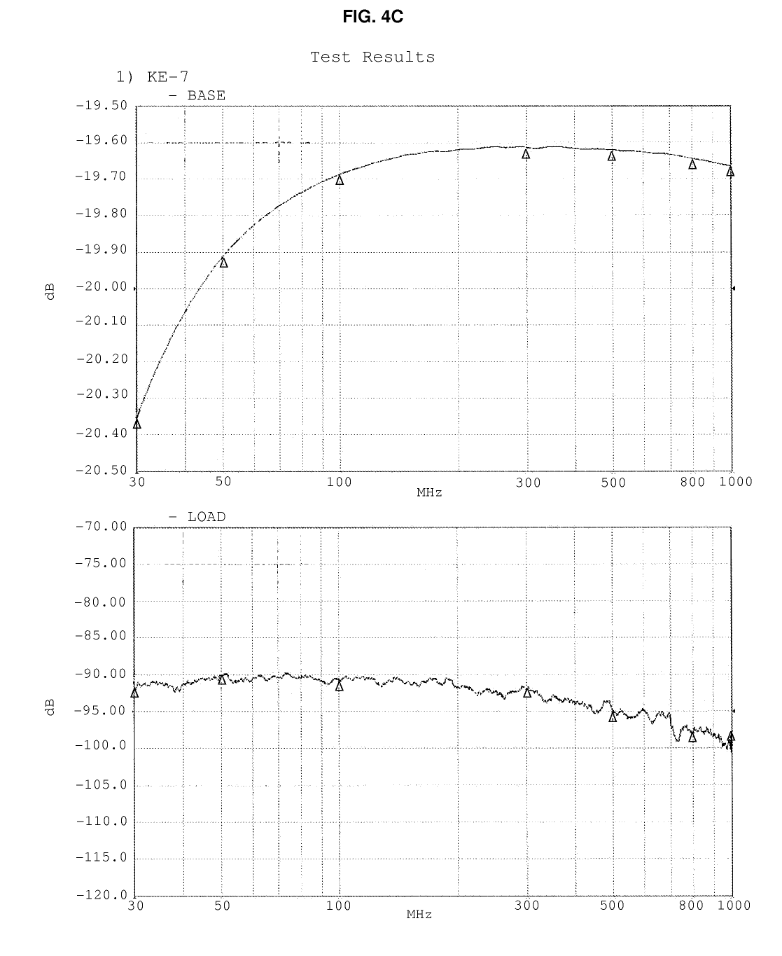

FIG. 4 illustrates the test certificate for electromagnetic shielding effectiveness of the mobile phone cover fabric (KE-7) manufactured according to a preferred embodiment of the present invention.

With reference to FIG. 4, electromagnetic shielding effectiveness was tested at different frequencies in the present invention. The inventive fabric exhibited a shielding effectiveness of 70 dB or more, ultimately 78.309 dB. Typically, the electromagnetic waves of mobile phones correspond to a high frequency of 900 MHz or more. The shielding effectiveness of the inventive fabric can be seen to be higher at high frequency based on the test results.

The present invention pertains to a mobile phone cover fabric having an electromagnetic shielding function and a method of manufacturing the same, and is useful in the fields related to mobile phone cover fabric having an electromagnetic shielding function and a method of manufacturing the same, wherein the electromagnetic shielding capability of mobile phones can be enhanced using a composition comprising a polycarbonate resin and carbon nanotubes.

1-9. (canceled)

10. A method of manufacturing a mobile phone cover fabric having an electromagnetic shielding function, comprising:
applying a polycarbonate resin composition on a release paper and drying the polycarbonate resin composition (S10);
applying a binder on the polycarbonate resin composition, and bonding-laminating an electromagnetic shielding fabric on the binder (S30);
drying the bonding-laminated electromagnetic shielding fabric and rolling the dried electromagnetic shielding fabric on a winder (S40); and
aging the rolled electromagnetic shielding fabric at 60-80° C. in an aging room (S50).

11. The method of claim 10, wherein the polycarbonate resin composition comprises 100 parts by weight of a polycarbonate resin, 10-25 parts by weight of dimethylformamide (DMF), 30-50 parts by weight of methyl ethyl ketone (MEK), 25-40 parts by weight of a toner and 2-7 parts by weight of an antimicrobial agent.

12. The method of claim 10, wherein the electromagnetic shielding fabric is formed by plating a fabric with a mixture of aluminum and nickel.

13. A method of manufacturing a mobile phone cover fabric having an electromagnetic shielding function, comprising:
applying, on a release paper, a first polycarbonate resin composition comprising 100 parts by weight of a polycarbonate resin, 10-25 parts by weight of dimethylformamide (DMF), 30-50 parts by weight of methyl ethyl ketone (MEK), 25-40 parts by weight of a toner and 2-7 parts by weight of an antimicrobial agent, and drying the first polycarbonate resin composition (S10);
applying, on the first polycarbonate resin composition, a second polycarbonate resin composition comprising 100 parts by weight of a polycarbonate resin, 10-25 parts by weight of dimethylformamide (DMF), 30-50 parts by weight of methyl ethyl ketone (MEK), and 10-20 parts by weight of carbon nanotubes for improving heat dissipation performance, and drying the second polycarbonate resin composition (S20);
applying a binder on the second polycarbonate resin composition, and bonding-laminating an electromagnetic shielding fabric on the binder (S30);
drying the bonding-laminated electromagnetic shielding fabric and rolling the dried electromagnetic shielding fabric on a winder (S40); and
aging the rolled electromagnetic shielding fabric at 60-80° C. in an aging room (S50).

14. The method of claim 13, wherein the electromagnetic shielding fabric is formed by plating a fabric with a mixture of aluminum and nickel.

15. A mobile phone cover fabric having an electromagnetic shielding function, comprising:
a polycarbonate resin layer comprising 100 parts by weight of a polycarbonate resin, 10-25 parts by weight of dimethylformamide (DMF), 30-50 parts by weight of methyl ethyl ketone (MEK), 25-40 parts by weight of a toner and 2-7 parts by weight of an antimicrobial agent;
a binder applied on the polycarbonate resin layer; and
an electromagnetic shielding fabric bonding-laminated on the binder.

16. The mobile phone cover fabric of claim 15, wherein the electromagnetic shielding fabric is formed by plating a fabric with a mixture of aluminum and nickel.

17. A mobile phone cover fabric having an electromagnetic shielding function, comprising:
a first polycarbonate resin layer comprising 100 parts by weight of a polycarbonate resin, 10-25 parts by weight of dimethylformamide (DMF), 30-50 parts by weight of methyl ethyl ketone (MEK), 25-40 parts by weight of a toner and 2-7 parts by weight of an antimicrobial agent;
a second polycarbonate resin layer applied on the first polycarbonate resin layer and comprising 100 parts by weight of a polycarbonate resin, 10-25 parts by weight of dimethylformamide (DMF), 30-50 parts by weight of methyl ethyl ketone (MEK), and 10-20 parts by weight of carbon nanotubes;
a binder applied on the second polycarbonate resin layer; and
an electromagnetic shielding fabric bonding-laminated on the binder.

18. The mobile phone cover fabric of claim 17, wherein the electromagnetic shielding fabric is formed by plating a fabric with a mixture of aluminum and nickel.
